(19) United States
(12) Patent Application Publication
(10) Pub. No.: US 2025/0260244 A1
(43) Pub. Date: Aug. 14, 2025

(54) POWER SUPPLY DEVICE AND METHOD FOR CONTROLLING THE SAME

(71) Applicant: HONDA MOTOR CO., LTD., Tokyo (JP)

(72) Inventor: Manabu Kurokawa, Tokyo (JP)

(21) Appl. No.: 19/050,165

(22) Filed: Feb. 11, 2025

(30) Foreign Application Priority Data
Feb. 14, 2024 (JP) 2024-020382

(51) Int. Cl. H02J 7/00; G01R 31/3835; H01M 10/625; H01M 10/63

(52) U.S. Cl. CPC H02J 7/0024; G01R 31/3835; H01M 10/63; H02J 7/0014; H02J 7/007; H01M 10/625

(57) ABSTRACT

A power supply device includes a first power source, a second power source, a switch circuit including a first switch to a third switch, a first reactor, a second reactor, and a control device configured to control the switch circuit and to alternately switch between a first state in which the first power source is connected between the first node and the fourth node via the first reactor and the second power source is connected to both ends of the second reactor and a second state in which the second power source is connected between the first node and the fourth node via the second reactor and the first power source is connected to both ends of the first reactor.

### CROSS-REFERENCE TO RELATED APPLICATION

Priority is claimed on Japanese Patent Application No. 2024-020382, filed Feb. 14, 2024, the content of which is incorporated herein by reference.

### BACKGROUND OF THE INVENTION

### Field of the Invention

The present invention relates to a power supply device and a method for controlling the same.

### Description of Related Art

In recent years, in order to realize a low-carbon society, an increasing number of vehicles have been equipped with a running motor instead of an engine as a power generation source, or vehicles have been equipped with a running motor in addition to an engine. The following Patent Documents 1 and 2 disclose battery control systems for raising a temperature of a battery that supplies power to a running motor of such a vehicle. For example, the battery control system disclosed in the following Patent Document 1 includes a first battery and a second battery of which output characteristics differ according to the temperature, and when the temperature of the first battery is below a predetermined temperature, the temperature of the first battery is raised by preferentially using the second battery.

[Patent Document 1] Japanese Unexamined Patent Application, First Publication No. 2020-092509

[Patent Document 2] Japanese Unexamined Patent Application, First Publication No. 2023-527451

### SUMMARY OF THE INVENTION

The battery control system disclosed in the above-described Patent Document 1 requires two batteries having different output characteristics according to the temperature, which leads to an increase in costs. In the battery control system disclosed in the above-described Patent Document 1, the temperature of the first battery is raised by arranging the second battery around the first battery, and thus it cannot be said that the batteries are effectively heated.

The aspects of the present invention have been made in consideration of the above circumstances, and an object thereof is to provide a power supply device and a method for controlling the same that can increase temperature of a plurality of power sources more efficiently than conventional methods without increasing costs by passing a high frequency current through them.

In order to solve the above problems and achieve the above object, the present invention employs the following aspects.
(1): A power supply device according to one aspect of the present invention is a power supply device which includes a first power source connected between a first node and a second node, and a second power source connected between a third node and a fourth node, the power supply device supplying power to an electrical load connected between the first node and the fourth node, including a switch circuit including a first switch connected between the first node and the third node, a second switch connected between the second node and the third node, and a third switch connected between the second node and the fourth node; a first reactor disposed between the first power source and the first node or the second node; a second reactor disposed between the second power source and the third node or the fourth node; and a control device configured to alternately switch between a first state in which the second switch and the third switch of the switch circuit are controlled to be in a closed state and the first switch is controlled to be in an open state, so that the first power source is connected between the first node and the fourth node via the first reactor and the second power source is connected to both ends of the second reactor and a second state in which the first switch and the second switch of the switch circuit are controlled to be in a closed state and the third switch is controlled to be in an open state, so that the second power source is connected between the first node and the fourth node via the second reactor and the first power source is connected to both ends of the first reactor.
(2): in the aspect (1), when switching between the first state and the second state is performed, the control device temporarily may control the first switch and the third switch to the open state and the second switch to the closed state to set a third state in which the first power source is connected between the first node and the fourth node via the first reactor and the second power source is connected between the first node and the fourth node via the second reactor.
(3): in the aspect (1) or (2), the power supply device may further include a voltage detection unit configured to detect a voltage of each of the first power source and the second power source, and the control device may perform balance control by alternately performing a first control in which the first switch is set to the closed state and the second switch and the third switch are set to the open state, and a second control in which the first switch, the second switch, and the third switch are set to the open state, when the voltage of the first power source is greater than the voltage of the second power source.
(4): in the aspect (1) or (2), the power supply device may further include a voltage detection unit configured to detect a voltage of each of the first power source and the second power source, and the control device may perform balance control by alternately performing a third control in which the first switch and the second switch are set to the open state and the third switch is set to the closed state, and a second control in which the first switch, the second switch, and the third switch are set to the open state, when the voltage of the second power source is greater than the voltage of the first power source.
(5): in the aspect (3) or (4), the control device may be configured to switch between a parallel state in which the first switch and the third switch are controlled to be in the closed state and the second switch is controlled to be in the open state, so that the first power source and the second power source are connected in parallel between the first node and the fourth node and a series state in which the first switch and the third switch are controlled to be in the open state and the second switch is controlled to be in the closed state, so that the first power source and the second power source are connected in series between the first node and the fourth node, and the balance control may be performed when a difference between a voltage of the first power source and a voltage of the second power source detected by the voltage detection unit is greater than or equal to a predetermined reference value and a transition to the parallel state is instructed.
(6): A method for controlling a power supply device according to one aspect of the present invention is a method for controlling a power supply device which includes a first power source connected between a first node and a second node, and a second power source connected between a third node and a fourth node, and supplies power to an electrical load connected between the first node and the fourth node, wherein the power supply device includes a switch circuit including a first switch connected between the first node and the third node, a second switch connected between the second node and the third node, and a third switch connected between the second node and the fourth node, a first reactor disposed between the first power source and the first node or the second node, and a second reactor disposed between the second power source and the third node or the fourth node, and the method includes a step of alternately switching between a first state in which the second switch and the third switch of the switch circuit are controlled to be in a closed state and the first switch is controlled to be in an open state, so that the first power source is connected between the first node and the fourth node via the first reactor and the second power source is connected to both ends of the second reactor and a second state in which the first switch and the second switch of the switch circuit are controlled to be in a closed state and the third switch is controlled to be in an open state, so that the second power source is connected between the first node and the fourth node via the second reactor and the first power source is connected to both ends of the first reactor.

According to the aspects (1) and (6), the open and closed states of the plurality of switches provided in the switch circuit are controlled to alternately switch between the first state and the second state. Thus, since a high frequency current can be applied to the first power source and the second power source, the first power source and the second power source can be heated more efficiently than before without increasing costs.

According to the aspect (2), when the first state and the second state are switched between, the first switch and the third switch are temporarily set to the open state and the second switch is temporarily set to the closed state, and thus it is possible to prevent the first switch and the third switch from being in the closed state at the same time.

According to aspects (3) and (4), since the balance control is performed in accordance with a magnitude relationship between the voltage of the first power source and the voltage of the second power source detected by the voltage detection unit, the voltage of the first power source and the voltage of the second power source can be made equal.

According to the aspect (5), when a difference between the voltage of the first power source and the voltage of the second power source detected by the voltage detection unit is greater than or equal to a predetermined reference value and a transition to a parallel state is instructed, the balance control is performed, and thus it is possible to curb a short-circuit current when transitioning to the parallel state.

### BRIEF DESCRIPTION OF THE DRAWINGS

FIG. 1 is a circuit diagram showing a configuration of a main part of a power supply device according to an embodiment of the present invention.

FIG. 2 is a diagram showing current paths when the power supply device according to the embodiment of the present invention is operating in a series mode or parallel mode.

FIG. 3 is a diagram showing the current path when the power supply device of the embodiment of the present invention is operating in a heating mode.

FIG. 4 is a diagram showing a current change when the power supply device of the embodiment of the present invention is operating in the heating mode.

FIG. 5 is a diagram showing a relationship between an amplitude of a current that flows when the power supply device according to the embodiment of the present invention is operating in the heating mode and a ratio (T/Tf).

FIG. 6 is a diagram showing a current path when the power supply device according to the embodiment of the present invention is operating in a first voltage balance mode.

FIG. 7 is a diagram showing a current change when the power supply device according to the embodiment of the present invention is operating in the first voltage balance mode.

FIG. 8 is a diagram showing a current path when the power supply device according to the embodiment of the present invention is operating in a second voltage balance mode.

FIG. 9 is a diagram showing a current change when the power supply device according to the embodiment of the present invention is operating in the second voltage balance mode.

FIG. 10 is a flowchart showing a process when voltage balance control is performed in the power supply device according to the embodiment of the present invention.

### DETAILED DESCRIPTION OF THE INVENTION

Hereinafter, embodiments of a power supply device and a method for controlling the same according to the present invention will be described with reference to the drawings.

### Power Supply Device

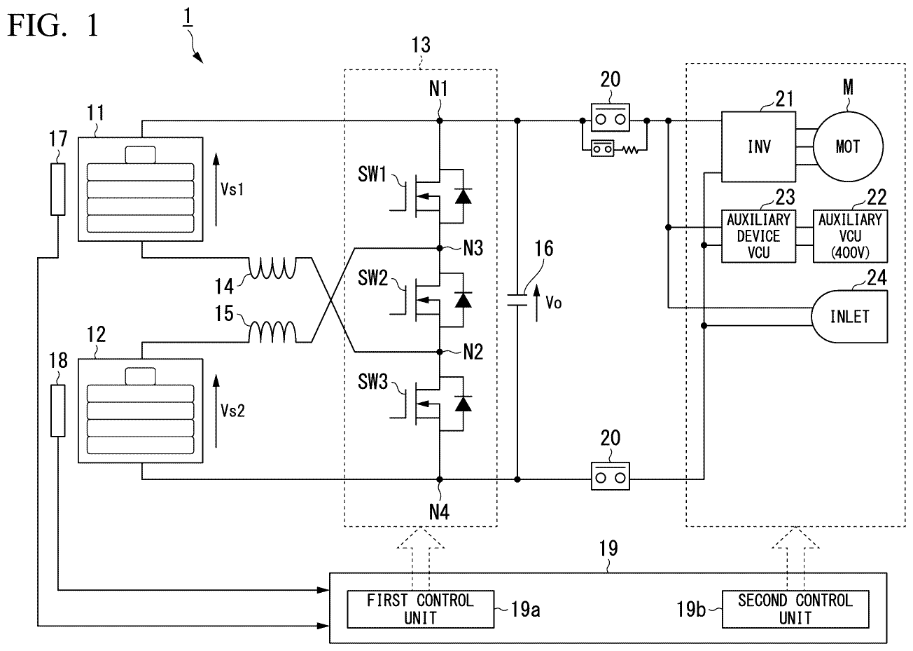

FIG. 1 is a circuit diagram showing a configuration of a main part of a power supply device according to an embodiment of the present invention. As shown in FIG. 1, the power supply device 1 according to this embodiment includes a first power source 11, a second power source 12, a switch circuit 13, a first reactor 14, a second reactor 15, a capacitor 16, a voltage detection unit 17, a voltage detection unit 18, and a control device 19. Such a power supply device 1 supplies DC power to an electrical load connected via a contactor 20, for example.

Here, examples of the electrical load to which DC power is supplied from the power supply device 1 include an inverter 21 that controls power running and regeneration of an electric motor M that generates a driving force for a vehicle, an auxiliary device 22 and an auxiliary voltage control unit (VCU) 23 provided in the vehicle, and an inlet 24 provided in the vehicle. In addition, for example, a three-phase brushless DC motor or the like can be used as the electric motor M. The auxiliary VCU 23 is a device that controls a voltage applied to the auxiliary device 22.

The first power source 11 is a chargeable and dischargeable secondary cell (for example, a battery or the like). A positive terminal of the first power source 11 is connected to a first node N1, and a negative terminal is connected to a second node N2. The second power source 12 is a chargeable and dischargeable secondary cell (for example, a battery or the like). A positive terminal of the second power source 12 is connected to a third node N3, and a negative terminal is connected to a fourth node N4. The first power source 11 and the second power source 12 are the same power sources, and a voltage Vs1 of the first power source 11 and a voltage Vs2 of the second power source 12 are equal (or approximately equal). The voltage Vs1 of the first power source 11 and the voltage Vs2 of the second power source 12 are voltages (for example, 400 V) suitable for operating the auxiliary device 22.

In addition, one end of the above-described electrical load (the inverter 21, the auxiliary VCU 23, and the inlet 24) is connected to the first node N1 via the contactor 20, and the other end is connected to the fourth node N4 via the contactor 20.

The switch circuit 13 includes three switching elements (a first switching element SW1 to a third switching element SW3 (a first switch to a third switch)) connected in series, and switches connection states of the first power source 11, the second power source 12, and the electrical load under the control of the control device 19. The first switching element SW1 is connected between the first node N1 and the third node N3, the second switching element SW2 is connected between the second node N2 and the third node N3. The third switching element SW3 is connected between the second node N2 and the fourth node N4.

Here, for example, metal-oxide-semiconductor field-effect transistors (MOSFETs) can be used as the first switching element SW1 to the third switching element SW3. When the MOSFETs are used as the first switching element SW1 to the third switching element SW3, specific connection relationships are as follows. A drain of the first switching element SW1 is connected to the first node N1, and a source thereof is connected to the third node N3. A drain of the second switching element SW2 is connected to the third node N3, and a source thereof is connected to the second node N2. A drain of the third switching element SW3 is connected to the second node N2, and a source thereof is connected to the fourth node N4. A diode is connected between the source and the drain of each of the first switching element SW1 to the third switching element SW3 in a forward direction from the source to the drain.

The switch circuit 13 is controlled to switch by, for example, a pulse width modulated (PWM) signal that is output from the control device 19 and input to gates of the first switching element SW1 to the third switching element SW3. A specific method for controlling the switching of the switch circuit 13 will be described below.

The first reactor 14 is disposed between the first power source 11 and the second node N2. More specifically, one end of the first reactor 14 is connected to the negative terminal of the first power source 11, and the other end is connected to a connection point between the source of the second switching element SW2 and the drain of the third switching element SW3. The second reactor 15 is disposed between the second power source 12 and the third node N3. More specifically, one end of the second reactor 15 is connected to the positive terminal of the second power source 12, and the other end is connected to a connection point between the source of the first switching element SW1 and the drain of the second switching element SW2.

The capacitor 16 is connected between the first node N1 and the fourth node N4. Specifically, one electrode of the capacitor 16 is connected to the first node N1, and the other electrode is connected to the fourth node N4. The capacitor 16 is provided to smooth a current output from the power supply device 1. The voltage detection unit 17 detects the voltage Vs1 of the first power source 11, and outputs a detection result thereof to the control device 19. The voltage detection unit 18 detects the voltage Vs2 of the second power source 12 and outputs a detection result thereof to the control device 19.

The control device 19 includes, for example, a first control unit 19a and a second control unit 19b, and performs switching control of the switch circuit 13 and control of the electrical load (for example, drive control of the inverter 21). The first control unit 19a performs the switching control of the switch circuit 13 to switch the connection states of the first power source 11, the second power source 12, and the electrical load.

Here, the power supply device 1 of the present embodiment has a parallel mode and a series mode as operation modes. The parallel mode is a mode in which the first power source 11 and the second power source 12 operate in a state in which they are connected in parallel to the electrical load (a parallel state). The series mode is a mode in which the first power source 11 and the second power source 12 operate in a state in which they are connected in series to the electrical load (a series state). The first control unit 19a controls the switch circuit 13 to switch between the parallel mode and the series mode.

The above-described operation modes include a heating mode and a voltage balance mode in addition to the above-described parallel mode and series mode. The heating mode is an operation mode in which the first power source 11 and the second power source 12 are heated by a chopper method. The voltage balance mode is an operation mode in which the voltage of the first power source 11 is equal to the voltage of the second power source 12. When the voltage of the first power source 11 is different from the voltage of the second power source 12, a short-circuit current flows from one of the first power source 11 and the second power source 12 to the other. In order to prevent this, the voltage balance mode is implemented. The operation modes and operation states of the power supply device 1 will be described in detail below.

The second control unit 19b controls the electrical load to which DC power is supplied from the power supply device 1. For example, in a power running operation of the electric motor M, the second control unit 19b converts the DC power applied between the positive and negative terminals of the inverter 21 on the DC side into three-phase AC power, and sequentially commutates the supply of power to each phase of the electric motor M to supply each phase of the AC current. On the other hand, for example, in a regenerative operation of the electric motor M, the second control unit 19b converts generated AC power output from the electric motor M into DC power while synchronization on the basis of a rotation angle of the electric motor M is maintained.

### Series Mode and Parallel Mode

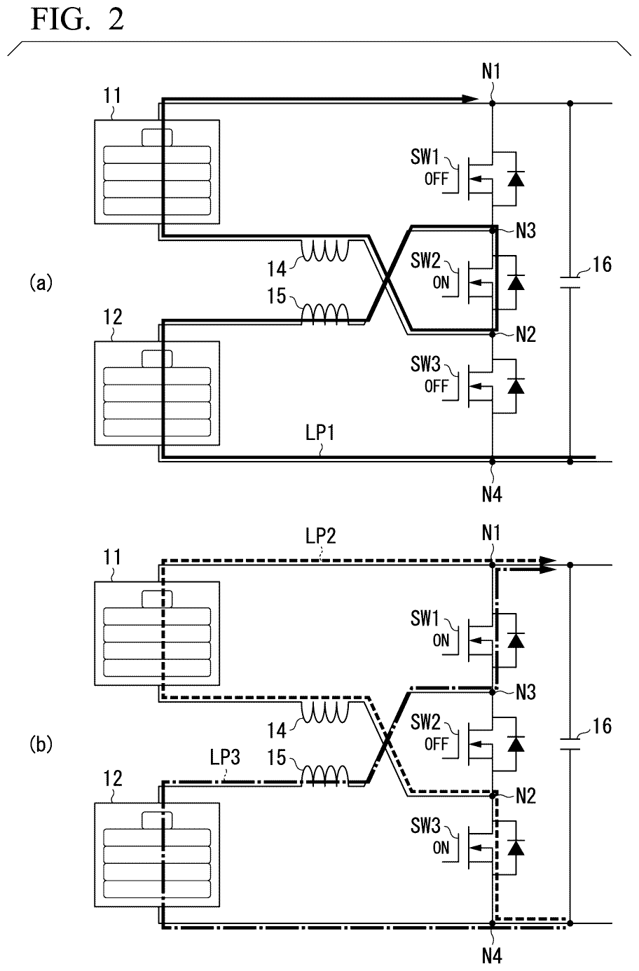

FIG. 2 shows the current paths when the power supply device according to the embodiment of the present invention is operating in a series or parallel mode. In addition, the voltage detection units 17 and 18, the control device 19, and the electrical load are not shown in FIG. 2. FIG. 2(a) is a diagram showing a current path when it is operating in the series mode, and FIG. 2(b) is a diagram showing a current path when it is operating in the parallel mode.

As shown in FIG. 2(a), in the series mode, the first control unit 19a of the control device 19 sets the second switching element SW2 to a closed state (ON) and sets the first switching element SW1 and the third switching element SW3 to an open state (OFF). Thus, as shown in FIG. 2(a), a current loop LP1 that passes through the fourth node N4, the second power source 12, the second reactor 15, the second switching element SW2, the first reactor 14, the first power source 11, and the first node N1 in this order is formed. That is, in the series mode, the first power source 11 and the second power source 12 are connected in series between the first node N1 and the fourth node N4. During the regeneration, a current flows in a direction opposite to a direction of a current in the current loop LP1 shown in FIG. 2(a).

As shown in FIG. 2(b), in the parallel mode, the first control unit 19a of the control device 19 sets the first switching element SW1 and the third switching element SW3 to the closed state (ON), and sets the second switching element SW2 to the open state (OFF). Thus, as shown in FIG. 2(b), a current loop LP2 that passes through the fourth node N4, the third switching element SW3, the first reactor 14, the first power source 11, and the first node N1 in this order, and a current loop LP3 that passes through the fourth node N4, the second power source 12, the second reactor 15, the first switching element SW1, and the first node N1 in this order are formed. That is, in the parallel mode, the first power source 11 and the second power source 12 are connected in parallel between the first node N1 and the fourth node N4. During regeneration, a current flows in a direction opposite to a direction of a current in the current loops LP2 and LP3 shown in FIG. 2(b).

### Heating Mode

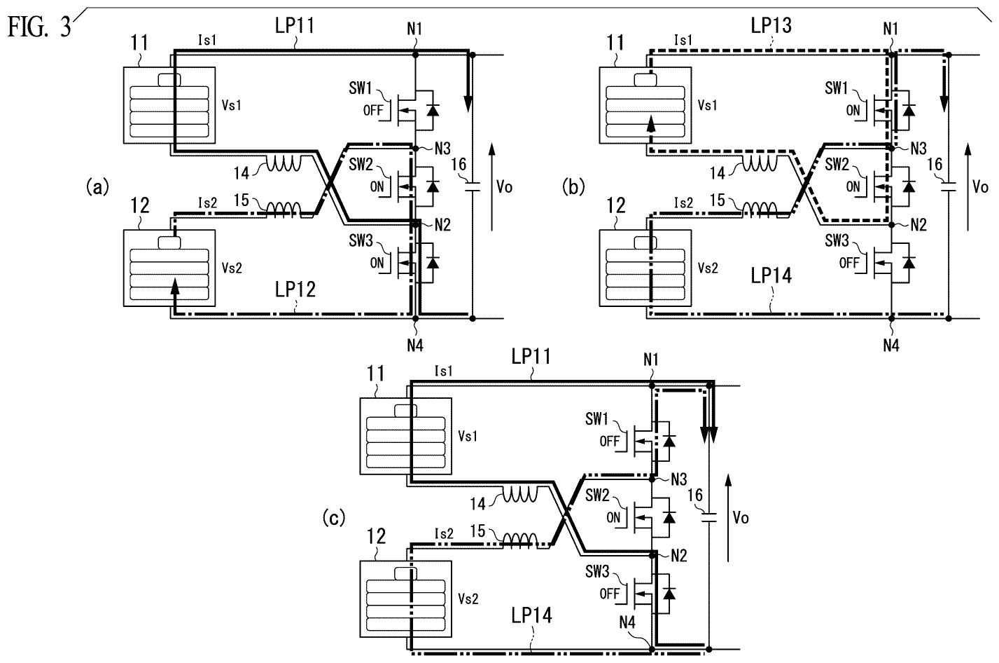

FIG. 3 is a diagram showing a current path when the power supply device according to the embodiment of the present invention is operating in the heating mode. As in FIG. 2, illustration of the voltage detection units 17 and 18, the control device 19, and the electrical load is omitted in FIG. 3. In the heating mode, the first control unit 19a of the control device 19 controls the switch circuit 13 to alternately switch between a first state shown in FIG. 3(a) and a second state shown in FIG. 3(b). A switching frequency between the first state and the second state is, for example, several tens to several hundreds of kHz.

Here, when the first state shown in FIG. 3(a) is switched to the second state shown in FIG. 3(b), the first control unit 19a first switches to the third state shown in FIG. 3(c) and then switches to the second state shown in FIG. 3(b). When the second state shown in FIG. 3(b) is switched to the first state shown in FIG. 3(a), the first control unit 19a first switches to the third state shown in FIG. 3(c) and then switches to the first state shown in FIG. 3(a).

Here, the above-described first state is a state in which the first power source 11 is connected between the first node N1 and the fourth node N4 via the first reactor 14, and the second power source 12 is connected to both ends of the second reactor 15. The above-described second state is a state in which the second power source 12 is connected between the first node N1 and the fourth node N4 via the second reactor 15, and the first power source 11 is connected to both ends of the first reactor 14. The above-described third state is a state in which the first power source 11 is connected between the first node N1 and the fourth node N4 via the first reactor 14, and the second power source 12 is connected between the first node N1 and the fourth node N4 via the second reactor 15.

As can be seen from FIGS. 3(a) to 3(c), in the heating mode, at least one of the first power source 11 and the second power source 12 is connected between the first node N1 and the second node N2.

As shown in FIG. 3(a), the first control unit 19a sets the above-described first state by setting the first switching element SW1 to the open state (OFF) and setting the second switching element SW2 and the third switching element SW3 to the closed state (ON). In the first state, a current loop LP11 that passes through the third switching element SW3, the first reactor 14, the first power source 11, and the capacitor 16 in this order is formed. A current loop LP12 which passes through the second power source 12, the second reactor 15, the second switching element SW2, and the third switching element SW3 in this order is also formed. The current loop LP11 is a current path in a state in which the first power source 11 is connected between the first node N1 and the fourth node N4 via the first reactor 14. The current loop LP12 is a current path in a state in which the second power source 12 is connected to both ends of the second reactor 15.

As shown in FIG. 3(b), the first control unit 19a sets the above-described second state by setting the first switching element SW1 and the second switching element SW2 to the closed state (ON) and setting the third switching element SW3 to the open state (OFF). In the second state, a current loop LP13 that passes through the first power source 11, the first switching element SW1, the second switching element SW2, and the first reactor 14 in this order is formed. A current loop LP14 which passes through the second power source 12, the second reactor 15, the first switching element SW1, and the capacitor 16 in this order is also formed. The current loop LP13 is a current path in a state in which the first power source 11 is connected to both ends of the first reactor 14. The current loop LP14 is a current path in a state in which the second power source 12 is connected between the first node N1 and the fourth node N4 via the second reactor 15.

As shown in FIG. 3(c), the first control unit 19a sets the above-described third state by setting the first switching element SW1 and the third switching element SW3 to the open state (OFF) and setting the second switching element SW2 to the closed state (ON). In the third state, the current loop LP11 shown in FIG. 3(a) and the current loop LP14 shown in FIG. 3(b) are formed. That is, in the third state, the first power source 11 and the second power source 12 are connected in parallel between the first node N1 and the fourth node N4.

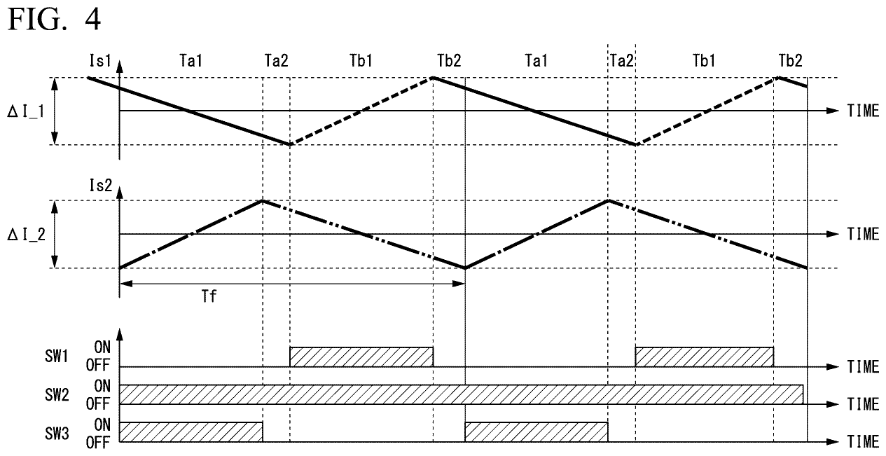

FIG. 4 is a diagram showing a current change when the power supply device according to the embodiment of the present invention is operating in the heating mode. In FIG. 4, a period during which the first state shown in FIG. 3(a) is set is defined as a period Ta1, and a period during which the second state shown in FIG. 3B is set is defined as a period Tb1. When the first state shown in FIG. 3(a) is switched to the second state shown in FIG. 3(b), a period during which the third state shown in FIG. 3(c) is temporarily set is defined as a period Ta2. When the second state shown in FIG. 3(b) is switched to the first state shown in FIG. 3(a), a period during which the third state shown in FIG. 3(c) is temporarily set is defined as a period Tb2.

As shown in FIG. 4, the first control unit 19a controls the first switching element SW1 to the third switching element SW3 of the switch circuit 13, and switches between the states shown in FIGS. 3(a) to 3(c). Specifically, the state is switched in sequence, for example, such as the first state (the period Ta1) shown in FIG. 3(a), the third state (the period Ta2) shown in FIG. 3(c), the second state (the period Tb1) shown in FIG. 3(b), the third state (the period Tb2) shown in FIG. 3(c), the first state (the period Ta1) shown in FIG. 3(a), . . .

In the period Ta1 during which the first state shown in FIG. 3(a) is set, the voltage Vs1 of the first power source 11 is lower than an output voltage Vo of the power supply device 1. Therefore, as shown in FIG. 4, a current Is1 flowing through the first power source 11 (a current flowing through the current loop LP11 shown in FIG. 3(a)) decreases. Specifically, when a reactance of the first reactor 14 is defined as L1, a rate of decrease of the current Is1 is expressed as dIs1/dt=(Vs1−Vo)/L1. On the other hand, the voltage Vs2 of the second power source 12 is higher than zero. Therefore, as shown in FIG. 4, a current Is2 flowing through the second power source 12 (a current flowing through the current loop LP12 shown in FIG. 3(a)) increases. Specifically, when a reactance of the second reactor 15 is defined as L2, a rate of increase of the current Is2 is expressed as dIs2/dt=Vs2/L2.

In the period Tb1 during which the second state shown in FIG. 3(b) is set, the voltage Vs1 of the first power source 11 is higher than zero. Therefore, as shown in FIG. 4, the current Is1 flowing through the first power source 11 (the current flowing through the current loop LP13 shown in FIG. 3(b)) increases. Specifically, the rate of increase of the current Is1 is expressed as dIs1/dt=Vs1/L1. On the other hand, the voltage Vs2 of the second power source 12 is lower than the output voltage Vo of the power supply device 1. Therefore, as shown in FIG. 4, the current Is2 flowing through the second power source 12 (the current flowing through the current loop LP14 shown in FIG. 3(b)) decreases. Specifically, the rate of decrease of the current Is2 is expressed as dIs2/dt=(Vs2−Vo)/L2.

In the periods Ta2 and Tb2 during which the third state shown in FIG. 3(c) is set, the voltage Vs1 of the first power source 11 and the voltage Vs2 of the second power source 12 are both lower than the output voltage Vo of the power supply device 1. Therefore, as shown in FIG. 4, the current Is1 flowing through the first power source 11 (the current flowing through the current loop LP11 shown in FIG. 3(c)) and the current Is2 flowing through the second power source 12 (the current flowing through the current loop LP14 shown in FIG. 3(c)) decrease. Specifically, the rate of decrease of the current Is1 is expressed as dIs1/dt=(Vs1−Vo)/L1, and the rate of decrease of the current Is2 is expressed as dIs2/dt=(Vs2−Vo)/L2.

Here, the voltage Vs1 of the first power source 11 and the voltage Vs2 of the second power source 12 are defined as voltages Vs (Vs1=Vs2=Vs). The reactance L1 of the first reactor 14 and the reactance L2 of the second reactor 15 are defined as reactance L (L1=L2=L). Furthermore, a length Ta of the period Ta1 during which the first state shown FIG. 3(a) is set and a length Tb of the period Tb1 during which the second state shown in FIG. 3(b) is set are defined as lengths T (Ta=Tb=T). In addition, a ratio of the length T of the period Ta1 or Tb1 to a switching cycle Tf (refer to FIG. 4) is set to 0.5 or less (T/Tf<0.5). Then, an amplitude ΔI_1 of the current Is1 flowing through the first power source 11 and an amplitude ΔI_2 of the current Is2 flowing through the second power source 12 are expressed as ΔI_1=ΔI 2=Vs×T/L.

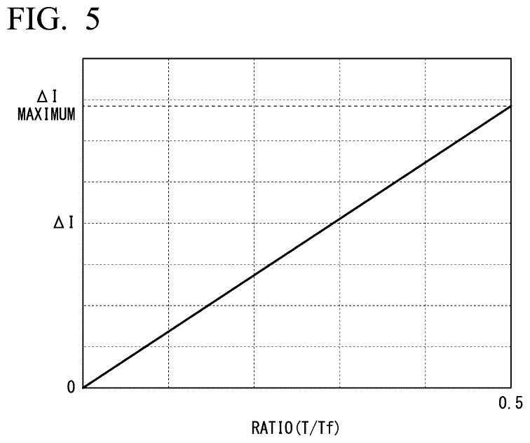

FIG. 5 is a diagram showing a relationship between the amplitude of the current that flows when the power supply device according to the embodiment of the present invention is operating in the heating mode and the ratio (T/Tf). With reference to FIG. 5, when it is operating in the heating mode, an amplitude ΔI of the current Is1 flowing through the first power source 11 and the current Is2 flowing through the second power source 12 is proportional to the ratio (T/Tf). The amplitude ΔI is zero when the ratio (T/Tf) is zero, and is maximum when the ratio (T/Tf) is 0.5.

That is, as the ratios of the period Ta2 and the period Tb2 in the switching cycle Tf shown in FIG. 4 increase, the amplitude ΔI of the current Is1 flowing through the first power source 11 and the current Is2 flowing through the second power source 12 decreases. On the other hand, as the ratios of the periods Ta2 and Tb2 in the switching cycle Tf shown in FIG. 4 decrease, the amplitude ΔI of the current Is1 flowing through the first power source 11 and the current Is2 flowing through the second power source 12 increases. Therefore, in order to efficiently heat the first power source 11 and the second power source 12, it is desirable to minimize the ratios of the period Ta2 and the period Tb2 in the switching cycle Tf shown in FIG. 4.

By performing the switching shown in FIG. 4, a boost operation of the first power source 11 and a boost operation of the second power source 12 are alternately performed in a state in which at least one of the first power source 11 and the second power source 12 is connected between the first node N1 and the second node N2. Thus, since a high frequency current can be applied to the first power source 11 and the second power source 12, the first power source and the second power source 12 can be heated more efficiently than before without increasing costs.

### Voltage Balance Mode

### First Voltage Balance Mode

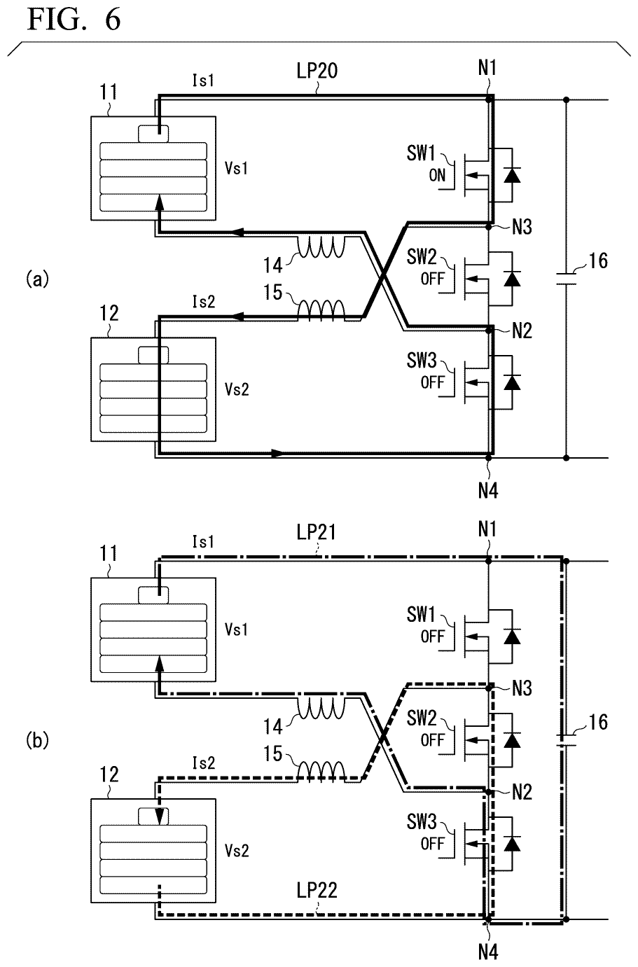

FIG. 6 is a diagram showing a current path when the power supply device according to the embodiment of the present invention is operating in the first voltage balance mode. As in FIGS. 2 and 3, illustration of the voltage detection units 17 and 18, the control device 19, and the electrical load is omitted in FIG. 6. The first voltage balance mode is performed in a case in which the voltage Vs1 of the first power source 11 is higher than the voltage Vs2 of the second power source 12, in order to make the voltage Vs1 of the first power source 11 and the voltage Vs2 of the second power source 12 equal to each other. In the first voltage balance mode, the first control unit 19a of the control device 19 controls the switch circuit 13 to alternately switch between an energy transfer state shown in FIG. 6(a) and an energy recovery state shown in FIG. 6(b).

Here, the energy transfer state shown in FIG. 6(a) is a state in which the first power source 11 and the second power source 12 are connected in parallel. The energy recovery state shown in FIG. 6(b) is a state in which the first power source 11 is connected via the capacitor 16, the third switching element SW3, and the first reactor 14, and the second power source 12 is connected to both ends of the second reactor 15.

In the energy transfer state shown in FIG. 6(a), electrical energy is transferred from the first power source 11 which has a higher voltage to the second power source 12. However, when a voltage difference between the first power source 11 and the second power source 12 is large, a peak value Ip of the current flowing through the first power source 11 and the second power source 12 becomes larger. Therefore, when a magnitude of the current flowing through the first power source 11 and the second power source 12 reaches a certain value, a transition to the energy recovery state is made to stop the transfer of electrical energy from the first power source 11 which has a higher voltage to the second power source 12.

In the energy recovery state shown in FIG. 6(b), in order to reduce the increased peak value Ip of the current flowing through the first power source 11 and the second power source 12, the electrical energy stored in the first reactor 14 and the second reactor 15 is recovered to the first power source 11 and the second power source 12, respectively. The energy recovery state shown in FIG. 6 continues until the current IS1 flowing through the first power source 11 and the current Is2 flowing through the second power source 12 both become zero.

As shown in FIG. 6(a), the first control unit 19a performs control (first control) to set the first switching element SW1 to the closed state (ON) and the second switching element SW2 and the third switching element SW3 to an open state (OFF), thereby achieving the above-described energy transfer state. In the energy transfer state, a current loop LP20 that passes through the first power source 11, the first switching element SW1, the second reactor 15, the second power source 12, the third switching element SW3, and the first reactor 14 in this order is formed. The current loop LP20 is a current path in a state in which the first power source 11 and the second power source 12 are connected in parallel.

As shown in FIG. 6(b), the first control unit 19a performs control (second control) to set the first switching element SW1 to the third switching element SW3 to the open state (OFF), thereby achieving the above-described energy recovery state. In the energy recovery state, a current loop LP21 that passes through the first power source 11, the capacitor 16, the third switching element SW3, and the first reactor 14 in this order is formed. A current loop LP22 that passes through the second power source 12, the third switching element SW3, the second switching element SW2, and the second reactor 15 in this order is also formed. The current loop LP21 is a current path in a state in which the first power source 11 is connected to both ends of the first reactor 14, and the current loop LP22 is a current path in a state in which the second power source 12 is connected to both ends of the second reactor 15.

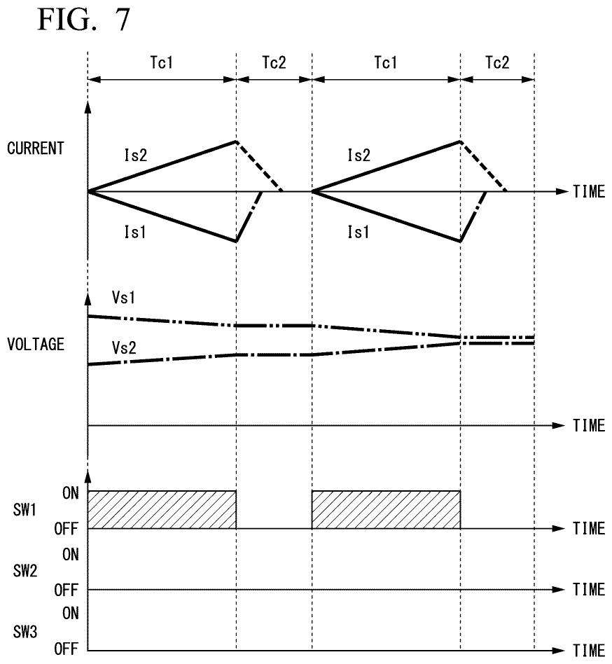

FIG. 7 is a diagram showing a current change when the power supply device according to the embodiment of the present invention is operating in the first voltage balance mode. In FIG. 7, a period during which the energy transfer state shown in FIG. 6(a) is set is defined as a period Tc1, and a period during which the energy recovery state shown in FIG. 6(b) is set is defined as a period Tc2. As shown in FIG. 7, the first control unit 19a controls the first switching element SW1 to the third switching element SW3 of the switch circuit 13 to alternately switch between the energy transfer state shown in FIG. 6(a) and the energy recovery state shown in FIG. 6(b).

In the period Tc1 during which the energy transfer state shown in FIG. 6(a) is set, the current Is1 flowing through the first power source 11 decreases, whereas the current Is2 flowing through the second power source 12 increases. When a time from the start of the period Tc1 is defined as t, the current Is2 flowing through the second power source 12 is expressed as Is2=(Vs1−Vs2)/(L1+L2)×t. When a length of the period Tc1 is defined as t_c1, the peak value Ip of the current Is flowing through the first power source 11 and the second power source 12 is expressed as Ip=(Vs1−Vs2)/(L1+L2)×t_c1.

In the period Tc2 in which the energy recovery state shown in FIG. 6(b) is set, the current Is1 flowing through the first power source 11 and the current Is2 flowing through the second power source 12 both decrease to zero. A time required for the current Is1 flowing through the first power source 11 to become zero is expressed as Vs1/L1×Ip. A time required for the current Is2 flowing through the second power source 12 to become zero is expressed as Vs2/L2×Ip. Therefore, a time t_c2 required for both the current Is1 flowing through the first power source 11 and the current Is2 flowing through the second power source 12 to become zero is a larger one of Vs1/L1×Ip and Vs2/L2×Ip.

When the switching shown in FIG. 7 is performed, as shown in the drawing, the voltage Vs1 of the first power source 11 gradually decreases, whereas the voltage Vs2 of the second power source 12 gradually increases. Then, by repeating the switching shown in FIG. 7, the voltage Vs1 of the first power source 11 and the voltage Vs2 of the second power source 12 become equal to each other. In this way, by performing the control in the first voltage balance mode (first voltage balance control), the voltage Vs1 of the first power source 11 and the voltage Vs2 of the second power source 12 become equal to each other.

### Second Voltage Balance Mode

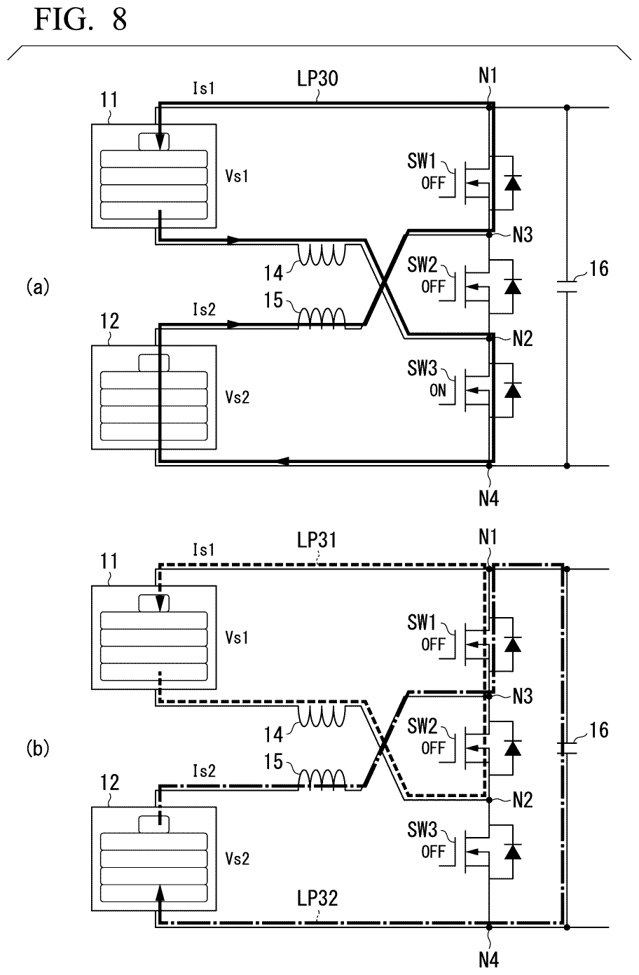

FIG. 8 is a diagram showing a current path when the power supply device according to the embodiment of the present invention is operating in a second voltage balance mode. As in FIGS. 2, 3 and 6, illustration of the voltage detection units 17 and 18, the control device 19 and the electrical load is omitted in FIG. 8. The second voltage balance mode is performed in a case in which the voltage Vs2 of the second power source 12 is higher than the voltage Vs1 of the first power source 11, in order to make the voltage Vs1 of the first power source 11 and the voltage Vs2 of the second power source 12 equal to each other. In the second voltage balance mode, the first control unit 19a of the control device 19 controls the switch circuit 13 to alternately switch between the energy transfer state shown in FIG. 8(a) and the energy recovery state shown in FIG. 8(b).

Here, the energy transfer state shown in FIG. 8(a) is a state in which the first power source 11 and the second power source 12 are connected in parallel, as in the energy transfer state shown in FIG. 6(a). The energy recovery state shown in FIG. 8(b) is a state in which the first power source 11 is connected to both ends of the first reactor 14, and the second power source 12 is connected via the second reactor 15, the first switching element SW1, and the capacitor 16.

In the energy transfer state shown in FIG. 8(a), electrical energy is transferred from the second power source 12 which has a higher voltage to the first power source 11. In the energy recovery state shown in FIG. 8(b), in order to reduce the increased peak value Ip of the current flowing through the first power source 11 and the second power source 12, the electrical energy stored in the first reactor 14 and the second reactor 15 is recovered to the first power source 11 and the second power source 12, respectively.

As shown in FIG. 8(a), the first control unit 19a performs control (third control) to set the first switching element SW1 and the second switching element SW2 to the open state (OFF) and the third switching element SW3 to the closed state (ON), thereby achieving the above-described energy transfer state. In the energy transfer state, a current loop LP30 that passes through the first power source 11, the first reactor 14, the third switching element SW3, the second power source 12, the second reactor 15, and the first switching element SW1 in this order is formed. The current loop LP30 is a current path in a state in which the first power source 11 and the second power source 12 are connected in parallel.

As shown in FIG. 8(b), the first control unit 19a performs control (second control) to set the first switching element SW1 to the third switching element SW3 to the open state (OFF), thereby achieving the above-described energy recovery state. In the energy recovery state, a current loop LP31 that passes through the first power source 11, the first reactor 14, the second switching element SW2, and the first switching element SW1 in this order is formed. A current loop LP32 that passes through the second power source 12, the second reactor 15, the first switching element SW1, and the capacitor 16 in this order is also formed. The current loop LP31 is a current path when the first power source 11 is connected to both ends of the first reactor 14, and the current loop LP32 is a current path when the second power source 12 is connected via the second reactor 15 and the capacitor 16.

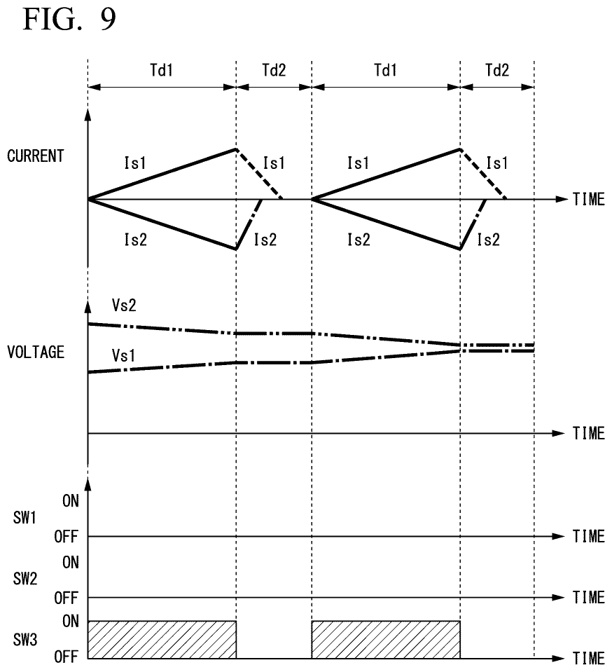

FIG. 9 is a diagram showing a current change when the power supply device according to the embodiment of the present invention is operating in the second voltage balance mode. In FIG. 9, a period during which the energy transfer state shown in FIG. 8(a) is set is defined as a period Td1, and a period during which the energy recovery state shown in FIG. 8(b) is set is defined as a period Td2. As shown in FIG. 9, the first control unit 19a controls the first switching element SW1 to the third switching element SW3 of the switch circuit 13 to alternately switch between the energy transfer state shown in FIG. 8(a) and the energy recovery state shown in FIG. 8(b).

In the period Td1 during which the energy transfer state shown in FIG. 8(a) is set, the current Is2 flowing through the second power source 12 decreases, whereas the current Is1 flowing through the first power source 11 increases. When a time from the start of the period Td1 is defined as t, the current Is1 flowing through the first power source 11 is expressed as Is1=(Vs2−Vs1)/(L1+L2)×t. When a length of the period Td1 is defined as t_d1, the peak value Ip of the current Is flowing through the first power source 11 and the second power source 12 is expressed as Ip=(Vs2−Vs1)/(L1+L2)×t_d1.

In the period Td2 during which the energy recovery state shown in FIG. 8(b) is set, the current Is1 flowing through the first power source 11 and the current Is2 flowing through the second power source 12 both decrease to zero. A time t_d2 required for the current Is1 flowing through the first power source 11 and the current Is2 flowing through the second power source 12 to both become 0 is larger one of Vs1/L1×Ip and Vs2/L2×Ip, similar to the time t_c2 when it is operating in the first voltage balance mode.

When the switching shown in FIG. 9 is performed, as shown in the drawing, the voltage Vs2 of the second power source 12 gradually decreases, whereas the voltage Vs1 of the first power source 11 gradually increases. Then, by repeating the switching shown in FIG. 9, the voltage Vs1 of the first power source 11 and the voltage Vs2 of the second power source 12 become equal to each other. In this way, by performing the control in the second voltage balance mode (second voltage balance control), the voltage Vs1 of the first power source 11 and the voltage Vs2 of the second power source 12 become equal to each other.

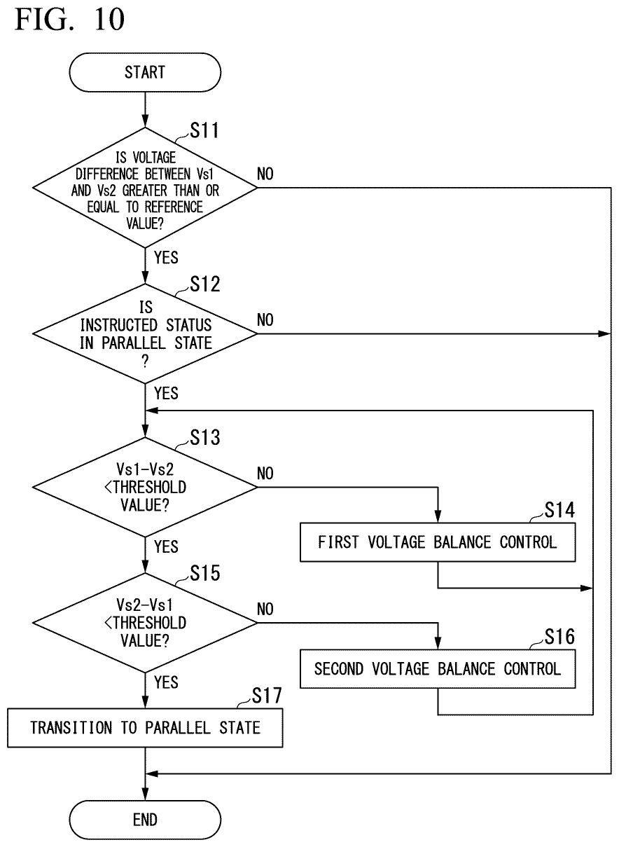

FIG. 10 is a flowchart showing a process when voltage balance control is performed in the power supply device according to the embodiment of the present invention. The flowchart shown in FIG. 10 is started, for example, every time a higher-level device (not shown) issues a transition instruction to a parallel connection to the control device 19 of the power supply device 1. Such a transition instruction is issued, for example, when the vehicle is started.

When the process is started, the first control unit 19a of the control device 19 determines whether a difference (a voltage difference) between the voltage Vs1 of the first power source 11 detected by the voltage detection unit 17 and the voltage Vs2 of the second power source 12 detected by the voltage detection unit 18 is greater than or equal to a predetermined reference value (Step S11). When the first control unit 19a determines that the voltage difference is not greater than or equal to the reference value, the process shown in FIG. 10 ends. On the other hand, when the first control unit 19a determines that the voltage difference is greater than or equal to the reference value, it determines whether a status instructed from the higher-level device is a parallel state (Step S12).

When the first control unit 19a determines that the status instructed from the higher-level device is not the parallel state, the first control unit 19a ends the process shown in FIG. 10. On the other hand, when the first control unit 19a determines that the status instructed from the higher-level device is the parallel state, the first control unit 19a determines whether a value obtained by subtracting the voltage Vs2 of the second power source 12 from the voltage Vs1 of the first power source 11 (hereinafter, referred to as a first potential difference) is smaller than a predetermined threshold value (Step S13).

When the first control unit 19a determines that the first potential difference is not smaller than the above-described threshold value (is greater than or equal to the above-described threshold value), it transitions to the first voltage balance mode described using FIGS. 6 and 7 and performs the first voltage balance control (Step S14). The first control unit 19a performs the first voltage balance control in Step S14 until it determines in Step S13 that the first potential difference is smaller than the threshold value. On the other hand, when the first control unit 19a determines that the first potential difference is smaller than the above-described threshold value, it determines whether a value obtained by subtracting the voltage Vs1 of the first power source 11 from the voltage Vs2 of the second power source 12 (hereinafter, referred to as a second potential difference) is smaller than a predetermined threshold value (Step S15).

When the first control unit 19a determines that the second potential difference is not smaller than the above-described threshold value (is greater than or equal to the above-described threshold value), it transitions to the second voltage balance mode described using FIGS. 8 and 9 and performs the second voltage balance control (Step S16). The first control unit 19a performs the second voltage balance control in Step S16 until it determines in Step S15 that the second potential difference is smaller than the threshold value. On the other hand, when the first control unit 19a determines that the second potential difference is smaller than the threshold value, it performs control to transition to the parallel state shown in FIG. 2(b) (Step S17). When the above-described process is completed, the first control unit 19a ends the process shown in FIG. 10.

As described above, the power supply device 1 of this embodiment includes the first power source 11 connected between the first node N1 and the second node N2, and the second power source 12 connected between the third node N3 and the fourth node N4. The power supply device 1 supplies power to an electrical load (such as the inverter 21, the auxiliary VCU 23, and the inlet 24) connected between the first node N1 and the fourth node N4.

The power supply device 1 includes the switch circuit 13, the first reactor 14, the second reactor 15, and the control device 19. The switch circuit 13 has the first switching element SW1 connected between the first node N1 and the third node N3, the second switching element SW2 connected between the second node N2 and the third node N3, and the third switching element SW3 connected between the second node N2 and the fourth node N4. The first reactor 14 is disposed between the first power source 11 and the first node N1 or the second node N2, and the second reactor 15 is disposed between the second power source 12 and the third node N3 or the fourth node N4.

The control device 19 alternately switches between the first state and the second state. The first state is a state in which the first power source 11 is connected between the first node N1 and the fourth node N4 via the first reactor 14, and the second power source 12 is connected to both ends of the second reactor 15. The second state is a state in which the first power source 11 is connected to both ends of the first reactor 14.

When the first state is set, the control device 19 sets the second switching element SW2 and the third switching element SW3 of the switch circuit 13 to the closed state and sets the first switching element SW1 to the open state. When the second state is set, the control device 19 sets the first switching element SW1 and the second switching element SW2 of the switch circuit 13 to the closed state and sets the third switching element SW3 to the open state.

Thus, by simply switching between the open state and the closed state of the plurality of switching elements provided in the switch circuit 13, a high frequency current can be applied to the first power source 11 and the second power source 12, and thus the first power source 11 and the second power source 12 can be heated more efficiently than before without increasing costs.

The above describes the form for carrying out the present invention using an embodiment, but the present invention is not limited to such an embodiment, and various modifications and substitutions can be made within the scope that does not deviate from the gist of the present invention. For example, in the above-described embodiment, the example in which the first reactor 14 is disposed between the first power source 11 and the second node N2, and the second reactor 15 is disposed between the second power source 12 and the third node N3 has been described. However, the first reactor 14 may be disposed between the first power source 11 and the first node N1. Similarly, the second reactor 15 may be disposed between the second power source 12 and the fourth node N4.

The control device 19 can be realized by a computer such as an embedded computer. When the control device 19 is realized by a computer, functions of each unit of the control device 19 are realized by executing a program for realizing the functions in a central processing unit (CPU) provided in the computer. In other words, the functions of each unit of the control device 19 are realized by cooperation of software and hardware resources. The control device 19 may be realized using hardware such as a field-programmable gate array (FPGA), a large scale integration (LSI), or an application specific integrated circuit (ASIC).

What is claimed is:

1. A power supply device which includes a first power source connected between a first node and a second node, and a second power source connected between a third node and a fourth node, the power supply device supplying power to an electrical load connected between the first node and the fourth node, comprising:
a switch circuit including a first switch connected between the first node and the third node, a second switch connected between the second node and the third node, and a third switch connected between the second node and the fourth node;
a first reactor disposed between the first power source and the first node or the second node;
a second reactor disposed between the second power source and the third node or the fourth node; and
a control device configured to alternately switch between a first state in which the second switch and the third switch of the switch circuit are controlled to be in a closed state and the first switch is controlled to be in an open state, so that the first power source is connected between the first node and the fourth node via the first reactor and the second power source is connected to both ends of the second reactor and a second state in which the first switch and the second switch of the switch circuit are controlled to be in a closed state and the third switch is controlled to be in an open state, so that the second power source is connected between the first node and the fourth node via the second reactor and the first power source is connected to both ends of the first reactor.

2. The power supply device according to claim 1, wherein when switching between the first state and the second state is performed, the control device temporarily controls the first switch and the third switch to the open state and the second switch to the closed state to set a third state in which the first power source is connected between the first node and the fourth node via the first reactor and the second power source is connected between the first node and the fourth node via the second reactor.

3. The power supply device according to claim 1, further comprising a voltage detection unit configured to detect a voltage of each of the first power source and the second power source,
wherein the control device performs balance control by alternately performing a first control in which the first switch is set to the closed state and the second switch and the third switch are set to the open state, and a second control in which the first switch, the second switch, and the third switch are set to the open state, when the voltage of the first power source is greater than the voltage of the second power source.

4. The power supply device according to claim 1, further comprising a voltage detection unit configured to detect a voltage of each of the first power source and the second power source,
wherein the control device performs balance control by alternately performing a third control in which the first switch and the second switch are set to the open state and the third switch is set to the closed state, and a second control in which the first switch, the second switch, and the third switch are set to the open state, when the voltage of the second power source is greater than the voltage of the first power source.

5. The power supply device according to claim 3, wherein the control device is configured to switch between a parallel state in which the first switch and the third switch are controlled to be in the closed state and the second switch is controlled to be in the open state, so that the first power source and the second power source are connected in parallel between the first node and the fourth node and a series state in which the first switch and the third switch are controlled to be in the open state and the second switch is controlled to be in the closed state, so that the first power source and the second power source are connected in series between the first node and the fourth node, and
the balance control is performed when a difference between a voltage of the first power source and a voltage of the second power source detected by the voltage detection unit is greater than or equal to a predetermined reference value and a transition to the parallel state is instructed.

6. A method for controlling a power supply device which includes a first power source connected between a first node and a second node, and a second power source connected between a third node and a fourth node, and supplies power to an electrical load connected between the first node and the fourth node,
wherein the power supply device includes a switch circuit including a first switch connected between the first node and the third node, a second switch connected between the second node and the third node, and a third switch connected between the second node and the fourth node, a first reactor disposed between the first power source and the first node or the second node, and a second reactor disposed between the second power source and the third node or the fourth node,
the method includes a step of alternately switching between a first state in which the second switch and the third switch of the switch circuit are controlled to be in a closed state and the first switch is controlled to be in an open state, so that the first power source is connected between the first node and the fourth node via the first reactor and the second power source is connected to both ends of the second reactor and a second state in which the first switch and the second switch of the switch circuit are controlled to be in a closed state and the third switch is controlled to be in an open state, so that the second power source is connected between the first node and the fourth node via the second reactor and the first power source is connected to both ends of the first reactor.
